(19) United States
(12) Patent Application Publication
(10) Pub. No.: US 2008/0160706 A1
(43) Pub. Date: Jul. 3, 2008

(54) METHOD FOR FABRICATING SEMICONDUCTOR DEVICE

(76) Inventor: Jin Hyo JUNG, Boosheon-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/964,108

(22) Filed: Dec. 26, 2007

(30) Foreign Application Priority Data
Dec. 27, 2006 (KR) 10-2006-0134620

(51) Int. Cl. H01L 21/336

(52) U.S. Cl. 438/297; 257/E21.409

(57) ABSTRACT

A method for fabricating a semiconductor device is provided, in which drift areas are deeply formed in a silicon substrate even when a drive-in process is performed at a relatively lower temperature for a relatively shorter processing time. Therefore, the defects caused by thermal bird's beaks and the horizontal diffusion of implanted impurities can be effectively suppressed. As a result, the punch-through property and the isolation property of high voltage components of the semiconductor device can be improved. Thus, the chip design size can be reduced.

### CROSS-REFERENCE TO RELATED APPLICATIONS

The present application claims the benefit of priority under 35 U.S.C. 119 to Korean Patent Application No. 10-2006-0134620, filed on Dec. 27, 2006, the entire contents of which are incorporated herein by reference.

### BACKGROUND

Embodiments consistent with the present invention relates to a method for fabricating a semiconductor device.

Generally, prior to a semiconductor device being formed on a semiconductor substrate, a device isolation process may be performed. In the device isolation process, a device isolation layer may be formed by performing a local oxidation of silicon (LOCOS) process. More specifically, the device isolation layer may be formed by selectively performing a thermal-oxidation process on the semiconductor substrate.

Bird's beaks may be created at opposite ends of the device isolation layer during the LOCOS process. The bird's beak may affect the operation of the semiconductor device in accordance with its size. A high voltage device or a high power device may not be affected by the size of the bird's beak. However, the high voltage device or the high power device may include logic components that are operated under a relatively low voltage. Accordingly, to reduce the design rule, a LOCOS process that may create bird's beaks of smaller sizes is generally used for fabricating the low voltage logic components.

In general, to reduce the design rule, a shallow trench isolation (STI) process has been used for fabricating semiconductor devices at a scale of less than 0.25 μm, instead of the LOCOS process.

FIG. 1 is a sectional view of a semiconductor device according to the related art.

As shown in FIG. 1, a semiconductor device, such as a drain extended metal-oxide-semiconductor (DEMOS) device, includes a substrate 11 having an active area and a device isolation area. A device separation layer 12 is formed in the device isolation area of substrate 11. A gate electrode 14 is formed in the active area of substrate 11 with a gate insulation layer 13 interposed between substrate 11 and gate electrode 14. N-drift areas 15 are formed in substrate 11 at both sides of gate electrode 14. Insulation sidewalls 16 are formed on both side surfaces of gate electrodes 14. Source/drain impurity areas 17 are formed in N-drift areas 15. At predetermined distances from both sides of gate electrode 14, metal silicide layers 19 are formed on gate electrode 14 and on source/drain impurity areas 17. A silicide block layer 18 is formed on N-drift areas 15 and insulation sidewalls 16 except at source/drain impurity areas 17. An etching-proof layer 20 and an interlayer dielectric film 21 are formed on substrate 11. Contact holes are formed by penetrating through etching-proof layer 20 and interlayer dielectric film 21, so as to partly expose a surface of metal silicide layer 19 on source/drain impurity area 17. Further, contact plugs 22 are formed in the contact holes to electrically contact metal silicide layer 19.

In a source/drain structure of the above-described semiconductor device of the related art, unlike a logic component structure, N-drift area 15 may be formed by deeply diffusing doped ions through a drive-in process after implanting N-type impurities in source/drain impurity areas 17 through a patterning and ion doping process, before gate electrode 14 is formed, so as to obtain a high junction breakdown voltage (BV).

Here, N-drift area 15 may be formed after gate electrode 14 is formed.

Since the drive-in process for forming N-drift area 15 requires a high temperature environment and a long processing time to realize the deep junction, a thermal budget may be increased. Thus, defects may be generated on or in substrate 11 due to the high drive-in temperature.

Furthermore, since the deeply implanted impurities may be diffused in a horizontal direction in the high temperature/long time drive-in process, the punch-through property of the high voltage (HV) DEMOS device may be deteriorated. Thus, it is difficult to realize a high voltage semiconductor device having a small channel size. Furthermore, since the separation property may also be deteriorated, the chip design may require an increased chip size.

On the other hand, when the drive-in process is insufficiently performed, the implanted impurities may not be deeply diffused. Thus, the drift area may not be deeply formed. In this case, the on-state breakdown voltage (BV) property of the HV DEMOS device may be significantly deteriorated.

### SUMMARY

Embodiments consistent with the present invention provide a method for fabricating a semiconductor device, which can improve a device property by forming a deep drift area while reducing a chip design size by improving punch-through and separation properties.

In one embodiment, a method for fabricating a semiconductor device includes implanting impurities in a substrate by performing first and second ion implanting processes, forming drift areas in the substrate by diffusing the impurities implanted through the first and second ion implanting processes through a drive-in process, forming a gate electrode on the substrate between the drift areas with a gate insulation layer interposed between the gate electrode and the substrate, forming source/drain impurity areas in the drift areas, the source/drain impurity areas being separated from the gate electrode by a predetermined distance, and forming a metal silicide layer on the source/drain impurity areas and on the gate electrode.

In another embodiment, a method of fabricating a semiconductor device includes forming a mask layer on a substrate, forming drift areas in the substrate at both sides of the mask layer, forming a punch-through-proof ion implantation layer in the substrate by implanting impurities in the substrate through a tilted ion implanting process using the mask layer as a mask, forming a gate electrode on the substrate between the drift areas with a gate insulation layer interposed between the gate electrode and the substrate, forming source/drain impurity areas in the substrate, the source/drain impurity areas being separated from the gate electrode by a predetermined distance, and forming a metal silicide layer on the source/drain impurity areas and on the gate electrode.

Detailed descriptions in accordance with one or more embodiments consistent with the present invention will be set forth in the following in conjunction with the accompanying drawings. Other features will be apparent from the detailed description and the drawings, and from the appended claims.

### BRIEF DESCRIPTION OF THE DRAWINGS

FIG. 1 is a sectional view illustrating a semiconductor device according to the related art.

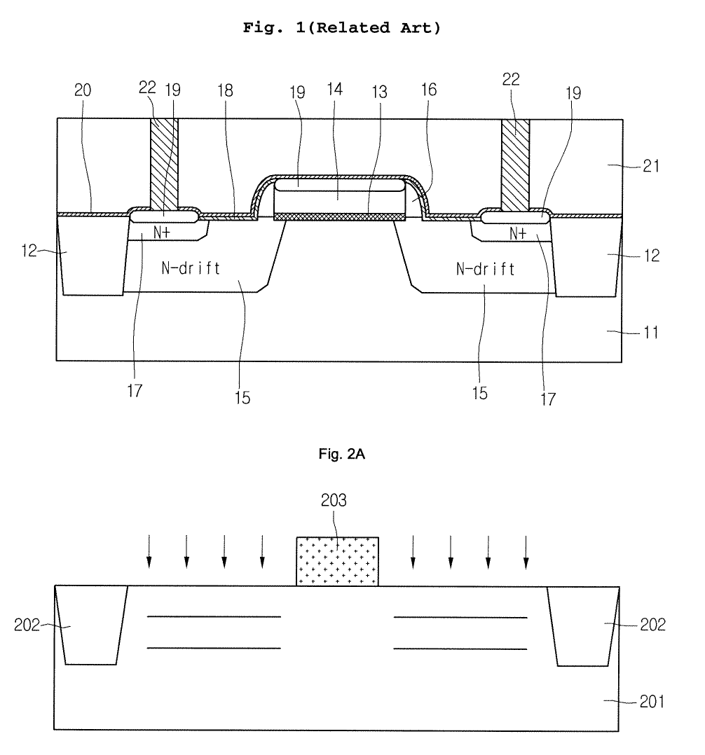

FIGS. 2A to 2E are sectional views illustrating a method for fabricating a semiconductor device, according to an embodiment consistent with the present invention.

FIG. 3 is a diagram illustrating a breakdown voltage property of a semiconductor device according to an embodiment consistent with the present invention.

FIG. 4 is a diagram illustrating a junction depth of N-drift areas of a semiconductor device according to an embodiment consistent with the present invention

FIG. 5 is a diagram illustrating an electric field and an impact ionizing ratio of a semiconductor device according to an embodiment consistent with the present invention.

### DETAILED DESCRIPTION

Any reference in this specification to “one embodiment,” “an embodiment,” “example embodiment,” etc., means that a particular feature described in connection with the “embodiment” is include in at least one embodiment consistent with the present invention. The appearances of such phrases in various places in the specification are not necessarily all referring to the same embodiment. Further, when a particular feature is described in connection with an embodiment, it is within the purview of one skilled in the art to effect such feature in connection with other possible embodiments.

Reference will now be made in detail to embodiments consistent with the present invention, examples of which are illustrated in the accompanying drawings.

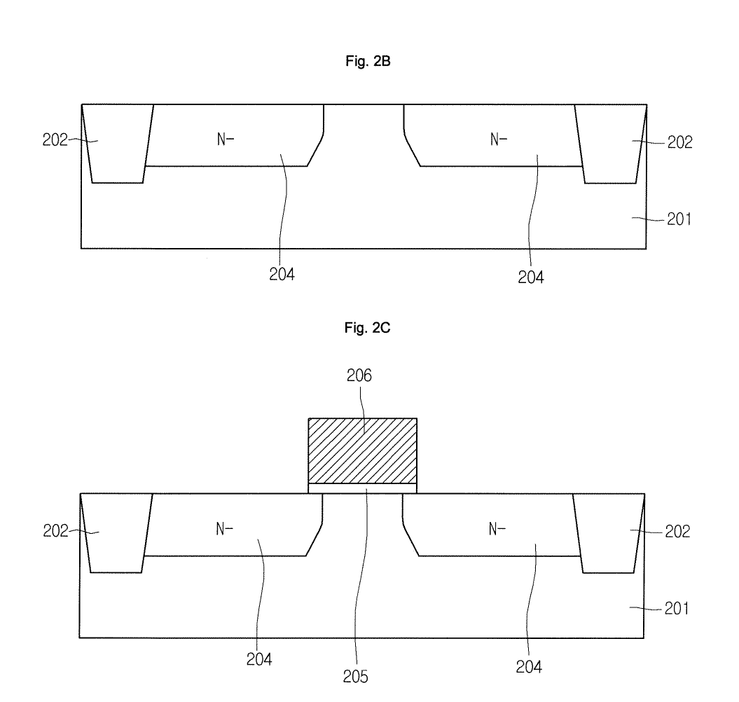

As shown in FIG. 2A, a semiconductor device includes a substrate 201 having an active area and a device isolation area. Device separation layers 202 are formed in the device isolation area of substrate 201, through a LOCOS process or an STI process.

Next, a photoresist layer is formed or deposited on an entire surface of substrate 201. The photoresist layer may be processed through an exposing and developing process to form a photoresist pattern 203, thereby defining drift forming areas.

N-type impurities may be implanted in substrate 201 using photoresist pattern 203 as a mask through first and second ion implanting processes.

Here, in the first ion implanting process, phosphor may be used to implant substrate 201 at an implantation energy of about 30-150 KeV. In addition, an implanting dose may be about 1.0E12 to about 5.0E13 [ions/cm²].

In addition, the first ion implanting process may implant the impurities in a vertical direction, at a predetermined tilting angle, or at the predetermined tilting angle while rotating substrate 201.

In the second ion implanting process, phosphor may be used to implant substrate 201 at an implantation energy of about 200-600 KeV. In addition, an implanting dose may be about 1.0E12 to about 5.0E13 [ions/cm²].

In addition, the second ion implanting process may implant the impurities in a vertical direction, at a predetermined tilting angle, or at the predetermined tilting angle while rotating substrate 201.

As shown in FIG. 2B, a drift-in process may be performed on substrate 201. In the drift-in process, impurities are implanted through the first and second ion implanting processes, at a relatively lower temperature for a relatively shorter processing time, thereby forming N-drift areas 204. In one embodiment, the drive-in process may be performed at a temperature of about 800-1200° C. for a processing time of about 10 minutes to about 15 hours.

Meanwhile, embodiments consistent with the present invention may be applied to manufacture a high voltage P-type DEMOS (HV DEPMOS) device or a high voltage N-type DEMOS (HV DENMOS) device to effectively form deep drift areas by implanting impurities through an ion implantation process of a relatively lower implantation energy and a drive-in process at a relatively low temperature for a relatively shorter processing time. In one embodiment, the impurities for the HV DEPMOS device may be boron (B).

Meanwhile, when forming the HV DEPMOS device, impurities such as phosphorous (P) and arsenic (As) may be implanted through the first and second ion implanting processes, and the drive-in process may be performed to form P-drift areas. Next, an ion implanting process may be performed for implanting punch-through-proof impurities in substrate 201, on which the P-drift areas are formed. In one embodiment, when forming the HV DEPMOS device, phosphor may be implanted in the first ion implanting process, and boron or indium may be implanted in the second ion implanting process to improve the punch-through property.

As shown in FIG. 2C, a gate insulation layer 205 is formed on substrate 201.

Next, a polysilicon layer is formed on gate insulation layer 205. The polysilicon layer and gate insulation layer 205 may be selectively etched to form gate electrode 206.

As shown in FIG. 2D, an insulation layer is formed on an entire surface of substrate 201 through, for example, a low-pressure chemical vapor deposition (LPCVD) process. An etch-back process may be performed through the entire surface of the insulation layer to form insulation sidewalls 207 on both side surfaces of gate electrode 206.

Next, a mask (not shown) may be formed on gate electrode 206 and insulation sidewalls 207, and around insulation sidewalls 207. Next, source/drain impurity areas 208 are formed in substrate 201 at N-drift areas 206. Source/drain impurity areas 208 may be spaced apart from gate electrode 206 by a predetermined distance.

As shown in FIG. 2E, a cleaning process may be performed to remove a variety of materials, such as metal impurities, an organic pollution material, and a natural oxide layer, formed on substrate 201.

Here, the cleaning process is generally performed through a chemical cleaning process using standard cleaning 1 (SC1) solution (an organic material where NH₄OH, H₂O₂, and H₂O are mixed in the ratio of 1:4:20), and HF or dilute HF solution.

Next, a silicide-proof layer 209 is formed on substrate 201 that has gone through the cleaning process. Silicide-proof layer 209 may be partly removed through a photolithography and etching process so that gate electrode 206 and source/drain impurity areas 208 are exposed.

A metal layer comprising, for example, cobalt, may be formed on the entire surface of substrate 201 through a physical vapor deposition (PVD) process or a chemical vapor deposition (CVD) process.

Instead of cobalt, titanium, tungsten, tantalum, or molybdenum, each of which has a high melting point, may be used to form metal layer.

Next, a heat treatment process may be performed to metal layer formed on substrate 201, so as to form a metal silicide layer 210 on gate electrode 206 and on source/drain impurity areas 208.

The portion of metal layer that does not react with substrate 201 nor gate electrode 206 is removed.

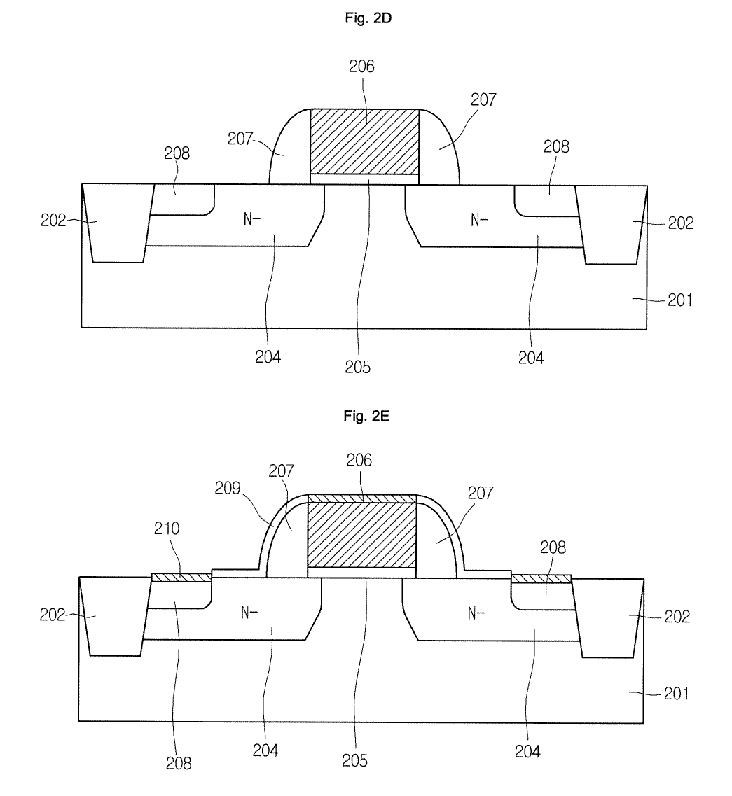

FIG. 3 shows a diagram illustrating a gate voltage vs. substrate current (Vg-Isub) property of the HV DENMOS device. The HV DENMOS device is in an on-state after impurities have been implanted through the two operations described above (i.e., the low energy ion implanting process and the high energy ion implanting process). Further, N-drift areas 204 are formed by performing the drive-in process at a temperature of 1000° C. for a time period of about 30 minutes. It can be noted from FIG. 3 that no breakdown voltage is observed even when a voltage of about 19 V is applied to the drain of the HV DENMOS device.

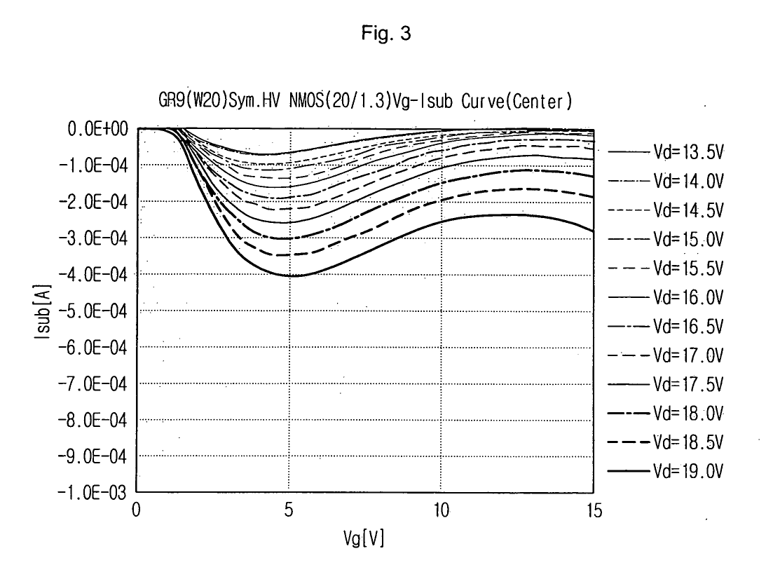

FIG. 4 shows a diagram illustrating a junction depth of N-drift areas 204, and a degree of horizontal diffusion when impurities are implanted through the two steps described above (i.e., the low energy ion implanting process and the high energy ion implanting process). The drive-in process is performed at a temperature of 1000° C. for a time period of about 30 minutes. It can be noted from FIG. 4 that the junction depth is about 0.85 μm and the horizontal diffusion is about 0.1 μm. That is, by applying the present invention, the junction depth may increase by 0.35 μm while maintaining similar horizontal diffusion.

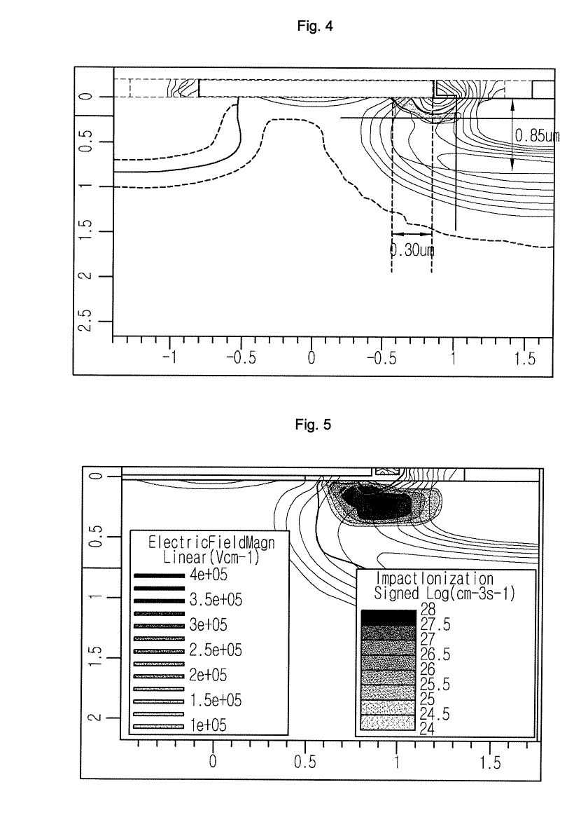

FIG. 5 shows a diagram illustrating an electric field and an impact ionizing ratio when impurities are implanted through the two steps described above (i.e., the low energy ion implanting process and the high energy ion implanting process). The drive-in process is performed at a temperature of about 1000° C. for a time period of about 30 minutes. It can be noted from FIG. 5. that, due to the increase of the junction depth, the electric field and the impact ionizing ratio are small. Accordingly, the on-state breakdown voltage property of the HV DENMOS device is improved.

As described above, in order to form N- or P-drift areas 204, impurities are implanted shallowly in substrate 201 through a first ion implanting process using a low energy. Subsequently, impurities are implanted deeply in substrate 201 through a second ion implanting process using a high energy.

Since the drive-in process is performed at a relatively lower temperature for a relatively shorter processing time in a state where the impurities are deeply doped in a vertical direction through the first and second ion implanting processes, as described above, N- or P-drift areas 204 can be effectively and deeply formed.

Alternatively, three ion implanting processes may be performed. That is, first, second, and third implanting processes that use respectively low, intermediate, and high energies may be performed. In addition, four or more ion implanting processes may be performed.

In addition, the ion implanting processes may implant the impurities in a vertical direction, in a direction tilted at a predetermined angle, or in the tilted direction while rotating the substrate 201, or a combination thereof.

Meanwhile, according to another embodiment consistent with the present invention, to improve the punch-through property of the process for fabricating the HV DEMOS and DEPMOS devices, a punch-through-proof ion implantation layer may be formed in substrate 201. At this point, the impurities are implanted through a tilted ion implantation by using the photoresist layer used for first and second processes for forming the drift areas as a mask without removing the photoresist layer. Therefore, an additional mask process can be omitted, and thus the fabrication cost can be reduced.

Although embodiments consistent with the present invention have been described with reference to a number of illustrative embodiments thereof, it should be understood that numerous other modifications and/or embodiments can be devised by those skilled in the art without departing from the spirit and scope of the appended claims. Moreover, various variations and modifications are possible in the component parts and/or arrangements of the subject combination arrangement that are within the scope of the appended claims. In addition to variations and modifications in the component parts and/or arrangements, alternative uses will also be apparent to those skilled in the art.

The method for fabricating the semiconductor device according to the embodiment described above has the following effects.

First, since drift areas 204 can be deeply formed even when the drive-in process is performed at a relatively lower temperature for a relatively shorter processing time, the defects caused by thermal bird's beaks and the horizontal diffusion of the implanted impurities can be effectively suppressed. As a result, the punch-through property and the isolation property of the high voltage components can be improved and thus the chip design size can be reduced.

Second, since drift areas 204 are deeply formed, the electric field and the impact ionizing ratio can be reduced, and thus the on-state breakdown voltage property of the high voltage components can be effectively improved.

Third, since the mask used for forming drift areas 204 is not removed but remain as a mask for forming the punch-through-proof ion implantation layer, an additional mask process can be omitted. Thus, the fabrication cost can be reduced.

What is claimed is:

1. A method for fabricating a semiconductor device, comprising:
implanting impurities in a substrate by performing first and second ion implanting processes;
forming drift areas in the substrate by diffusing the impurities implanted through the first and second ion implanting processes through a drive-in process;
forming a gate electrode on the substrate between the drift areas with a gate insulation layer interposed between the gate electrode and the substrate;
forming source/drain impurity areas in the drift areas, the source/drain impurity areas being separated from the gate electrode by a predetermined distance; and
forming a metal silicide layer on the source/drain impurity areas and on the gate electrode.

2. The method according to claim 1, wherein performing the first ion implanting process comprises implanting the impurities at an implanting energy of about 30 KeV to about 150 KeV and an implanting dose of about 1.0E12 ions/cm² to about 5.0E13 ions/cm².

3. The method according to claim 1, wherein performing the first ion implanting process comprises implanting the impurities at an implanting energy of about 200 KeV to about 650 KeV and an implanting dose of about 1.0E12 ions/cm² to about 5.0E13 ions/cm².

4. The method according to claim 1, wherein the drive-in process is performed at a temperature of about 800° C. to about 1200° C. for a time period of about 10 minutes to about 15 hours.

5. The method according to claim 1, further comprising, after forming the source-drain impurity areas, cleaning the substrate through a chemical cleaning process using standard cleaning solution comprising an organic material with NH₄OH, H₂O₂, and H₂O mixed in a ratio of 1:4:20, and HF or dilute HF solution.

6. A method of fabricating a semiconductor device, comprising:
forming a mask layer on a substrate;
forming drift areas in the substrate at both sides of the mask layer;
forming a punch-through-proof ion implantation layer in the substrate by implanting impurities in the substrate through a tilted ion implanting process using the mask layer as a mask;
forming a gate electrode on the substrate between the drift areas with a gate insulation layer interposed between the gate electrode and the substrate;
forming source/drain impurity areas in the substrate, the source/drain impurity areas being separated from the gate electrode by a predetermined distance; and
forming a metal silicide layer on the source/drain impurity areas and on the gate electrode.

7. The method according to claim 6, wherein the tilted ion implantation process comprises first and second ion implantation processes.

8. The method according to claim 6, wherein the tilted ion implanting process comprises implanting the impurities at a predetermined angle on the substrate.

9. The method according to claim 6, wherein the tilted ion implanting process comprises implanting the impurities while rotating the substrate.
